(19) United States
(12) Patent Application Publication
(10) Pub. No.: US 2016/0270260 A1
(43) Pub. Date: Sep. 15, 2016

(54) MANIFOLDS HAVING SLIDABLE DRIPLESS CONNECTORS

(71) Applicant: HEWLETT PACKARD ENTERPRISE DEVELOPMENT LP, Houston, TX (US)

(72) Inventor: John P Franz, Houston, TX (US)

(21) Appl. No.: 15/033,111

(22) PCT Filed: Jan. 6, 2014
(86) PCT No.: PCT/US2014/010322

§ 371 Date: Apr. 29, 2016

(51) Int. Cl. H05K 7/20

(52) U.S. Cl. CPC H05K 7/20272

(57) ABSTRACT

An example device in accordance with an aspect of the present disclosure includes a dripless connector that has a base and an extension. A manifold is to slidably mount the dripless connector. The base of the dripless connector is slidable, relative to the manifold, along a floating direction substantially non-parallel to an engagement direction of the extension of the dripless connector.

### BACKGROUND

Computing systems may be cooled using various techniques, such as air cooling and water cooling. Water cooling systems may use hoses and fittings, based on manual installation and removal of clamps and other equipment to ensure proper retention and seal.

### BRIEF DESCRIPTION OF THE DRAWINGS/FIGURES

FIG. 1 is a block diagram of a system including a dripless connector according to an example.

FIG. 2A is a block diagram of a system including a dripless connector in a first position according to an example.

FIG. 2B is a block diagram of a system including a dripless connector in a second position according to an example.

FIG. 3A is a side view of a system including a dripless connector according to an example.

FIG. 3B is a front view of a system including a dripless connector according to an example.

FIG. 4A is a perspective view of a manifold according to an example.

FIG. 4B is a partially exploded perspective view of a system including a manifold and a dripless connector according to an example.

FIG. 5A is a perspective view of a system including a manifold according to an example.

FIG. 5B is a perspective section view of a system including a manifold according to an example.

FIG. 8A is a section view, taken along line A-A of FIG. 4B, of a system including a dripless connector according to an example.

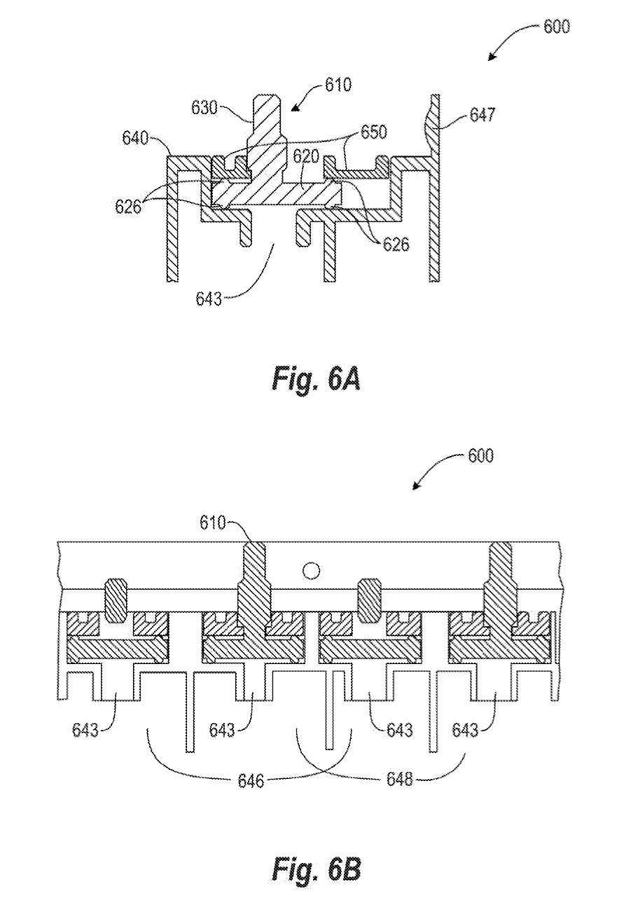

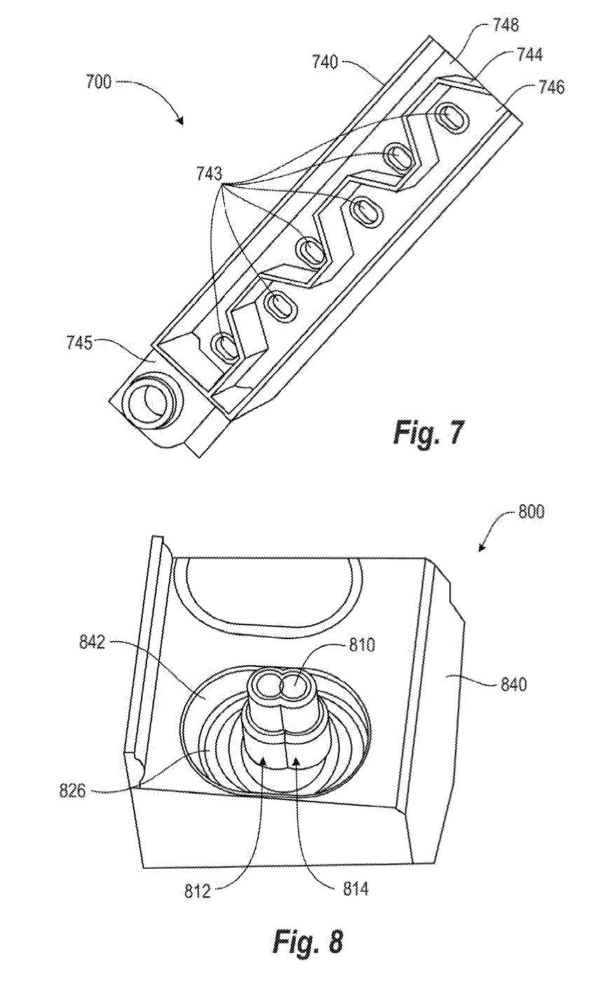

FIG. 6B is a section view, taken along line B-B of FIG. 4B, of a system including a dripless connector according to an example.

FIG. 7 is a perspective view of a system including a manifold according to an example.

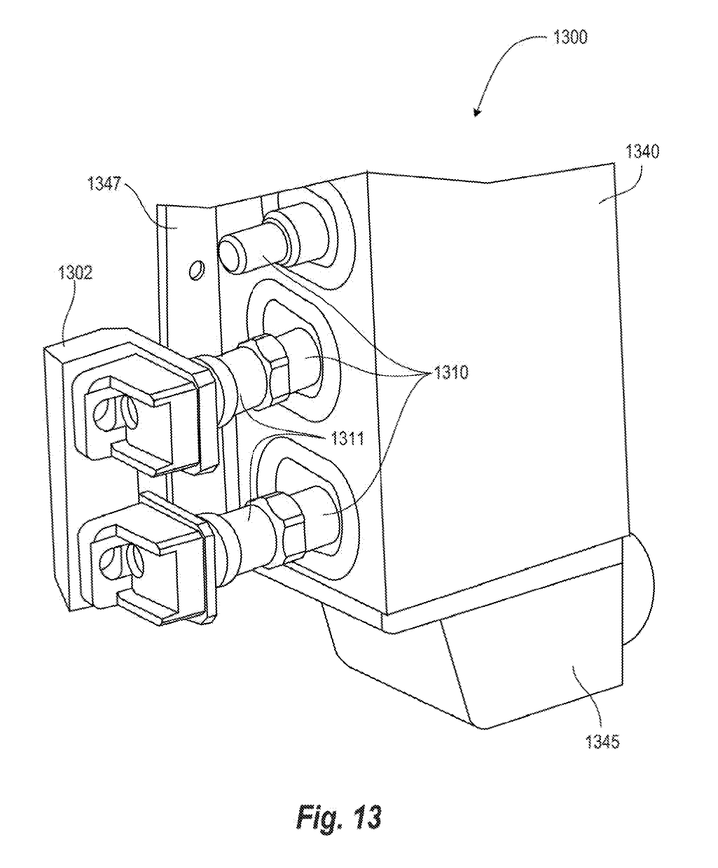

FIG. 8 is a perspective view of a system including a manifold and dripless connector according to an example.

FIG. 9 is a perspective view of a dripless connector according to an example.

FIG, 10 is a perspective view of a female dripless connector according to an example.

FIG. 11 is a perspective view of a cap according to an example.

FIG. 12 is a perspective section view of a cap according to an example.

FIG. 13 is a perspective view of a system including a dripless connector according to an example.

### DETAILED DESCRIPTION

Servicing water-cooled arrangements may be difficult, time consuming, and expensive. Disassembly incurs risks that other elements in the nearby assemblies could be damaged, and imposes a need to shutdown otherwise functional units to drain the assembly. A leak in any of the elements may drain the assembly and put other units at risk of overheating, as well as causing water damage.

Example systems provided herein may provide thermal services (e.g., cooling) to a computing system such as a server and/or rack of servers, based on a blind mate dripless connector (e.g., a connector including an automatic integrated shut-off valve). The dripless connector may “float” or translate to accommodate movements associated with assembly, shipping, installation, usage, or other events such as vibration, accidents, earthquakes, and so on. Examples may be constructed in increments of one rack unit (i.e., 1U), to match sizes of various servers. The floating dripless connector may accommodate movement of the computing system within a rack, and/or movement of an element/component within a computing system.

Examples based on the floating dripless connector may enable enhanced serviceability, reliability, thermal performance, and cost reductions for computing systems. Fluid couplings may be achieved without the use of hoses that are difficult to install, such that example cooling solutions may include individual flow control shut-off for each 1U cooling unit. Server issues (e.g., failures) or other service events may be addressed individually, without needing to shut down and/or disassemble large groups of servers and stop water flow simultaneously to large portions of the rack to remove an entire cooling wall assembly. The blind mate floating dripless connector enables the capability to diagnose and investigate issues at an individual level, without needing to disassemble an entire rack to remove one computing system. Additionally, examples described herein enable easy upgrades to a particular computing system, without the difficulty associated with disassembling and/or interrupting cooling to the entire rack/system.

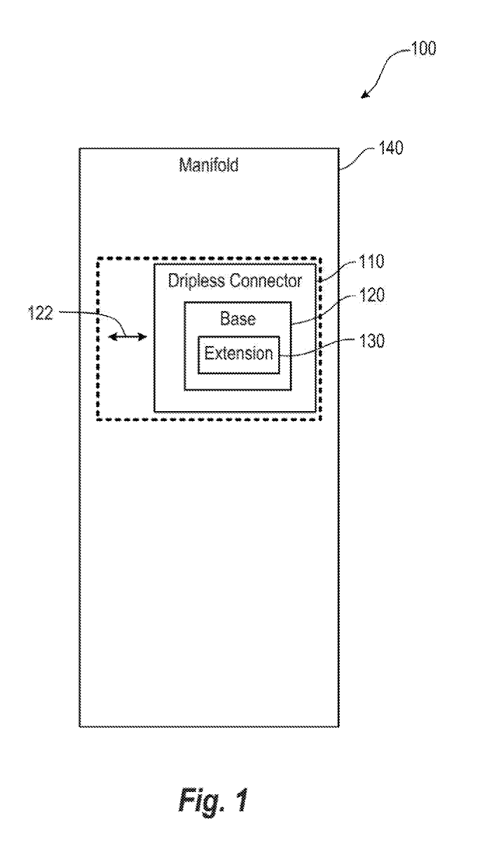

FIG. 1 is a block diagram of a system 100 including a dripless connector 110 according to an example. The dripless connector 110 is slidably mounted to a manifold 140. The dripless connector 110 includes a base 120 and an extension 130.

The dripless connector 110 is slidable along a floating direction 122. The extension 130 is associated with an engagement direction that is substantially non-parallel to the floating direction, e.g., into and out of the page as shown in FIG. 1. Accordingly, the extension 130 may engage another element to establish a fluid flow through the dripless connector 110, based on a blind mate snap-together fit independent of the floating direction. Additionally, the dripless connector 110 is slidable without needing to disengage or otherwise affect the connection established by the extension 130, ensuring a reliable fluid seal even when components shift or move. As used herein, the terms slidable, floating, movable, and so on may include omnidirectional movements, e.g., along multiple axes. Accordingly, example dripless connectors 110 may be slidable along an X-axis and Y-axis, which are substantially non-parallel to the engagement direction (i.e., the Z-axis). In an example, the X-axis may be along a major axis of an elongated recess in the manifold, and the Y-axis may be along a minor axis of the recess, Accordingly, a recess in the manifold (or other non-recessed corresponding feature of the manifold to receive the dripless connector) may be larger than a corresponding dripless connector to be received at the recess. The omnidirectional slidability of the dripless connector may be based on omnidirectional clearances between the dripless connector and the manifold, to accommodate the floating dripless connector while enabling a fluid seal.

The manifold 140 may be provided at a rack or computing system. The manifold 140 may provide a fluid supply and fluid return for a plurality of dripless connectors 110, such that a dripless connector 110 may be used for supplying fluid (e.g., cool fluid) or returning fluid (e.g., warm fluid). Various fluids may be used, such as coolant based on water or all, or other materials having desirable characteristics for heat transfer.

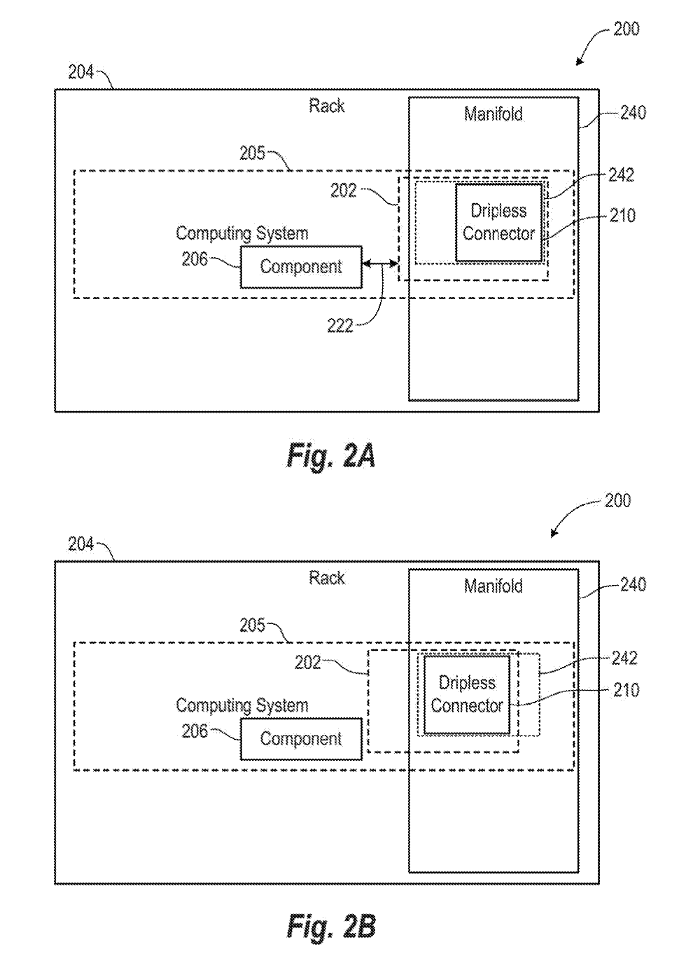

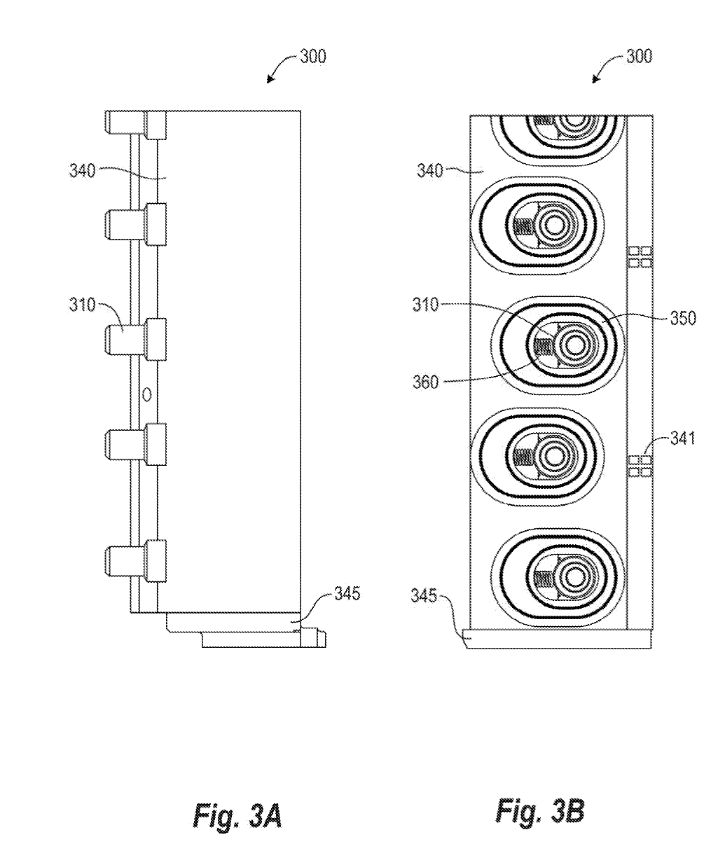

FIG. 2A is a block diagram of a system 200 including a dripless connector 210 in a first position according to an example. The system 200 includes a rack 204 to house a manifold 240 and receive a computing system 205. The manifold 240 includes a recess 242 in which the dripless connector 210 is slidably mounted. The rack 204 includes an element 202, to which the dripless connector 210 is engaged. The element 202 and dripless connector 210 are slidable, while engaged, in the floating direction 222. The element 202 may be a thermal bus bar (TBB) that is movable within the rack 204. As shown, the element 202 is moved away from component 206, allowing a gap between the element 202 and the component 206 to enable easy installation of the computing system 205 in the rack 204. The gap allows the computer system 205 or components therein to be installed without risking contact and/or damage to the computer system components or element 202, while using improved tolerances for a very snug fit after the gap is closed. In alternate examples, the dripless connector 210 may be connected directly to a component 206 (e.g., to the computing system 205, or to a heat-generating element of the computing system 205, directly or indirectly).

The manifold 240 may form a wall structure within the rack 204 to provide fluid flow, as a rack-based cooling solution. In an alternate example, a manifold 240 may be provided at a computing system 205 directly, as an individual server-based cooling solution in the server. The manifold 240 may be formed of metal such as aluminum. Systems 200 may be pre-assembled and shipped. During assembly, shipping, and/or site installation, an integrated structure of multiple servers 205 in system 200 may experience shifting/movement. The floating dripless connector 210 can move along the floating direction 222, to absorb shock and vibe and prevent damage or leaks, in contrast to a fixed rigid connector fitted directly to a member. The dripless connector 210 enables protection even in earthquakes or other unusual situations, in addition to shipping and normal use of system 200.

In examples where element 202 is a TBB, heat may be transferred away from the computing system 206 (i.e., component 206) through a dry thermal pad interface between component 206 and element (TBB) 202, where TBB 202 circulates fluid to remain cool without circulating fluid through component 206. The TBB 202 is movable to close an air gap between the TBB 202 and the component 206. Thus, thermal connection between the TBB 202 and the component 206 may be achieved by moving the TBB 202 over to compress against the component 206 with a high amount of precision and force, for heat transfer to the TBB 202 and its internal circulating fluid.

Thus, the manifold 240 may be set into the rack 204 to remain immobile relative to the computing system 230 and/or component 206. In an alternate example, the manifold 240 may serve as a structural support for the rack 204 and/or computing system 230.

FIG. 2B is a block diagram of a system 200 including a dripless connector 210 in a second position according to an example. The dripless connector 210 has remained engaged to the element 202, which has translated the dripless connector 210 along a floating direction. The element 202 is in contact with the component 206 (i.e., having closed the air gap between the element 202 and the component 206). Accordingly, the dripless connector 210 has maintained a fluid seal with the element 202 and manifold 240, while sliding relative to the manifold 240.

An element 202 (e.g., TBB) may be provided at computing system 205, such that a plurality of computing systems 205 (e.g., servers) may be provided with their own respective element 202 that communicates via a corresponding dripless connector 210 to the manifold 240. Thus, the manifold 240 may be associated with a plurality of independently slidable dripless connectors 210. A computing system 205 may provide a handle to actuate side-to-side movement for engaging element 202 with the component 206.

In an example, a manifold 240 may include ten dripless connectors 210 that communicate via supply/return paths of the manifold 240. The plurality of dripless connectors 210 are independently movable/slidable along the floating direction 222, and a computing system 205 may be independently disconnected from its dripless connector 210 without disrupting fluid flow or operation of other computing systems 205. A plurality of computing systems 205 may be integrated into a Performance Optimized Datacenter (POD) and shipped assembled together as a unit, whereby the floating dripless connector 210 may avoid problems from stress/shock/vibe experienced by the entire POD. In an alternate example, the computing system 205 may be a liquid-cooled server where the dripless connector 210 connects directly to the computing system 205 (i.e., without using the element 202). The dripless connector 210 may be self-aligning, including a lead-in and/or angled funnel to self-align and mate the dripless connector 210, regardless of its location along the floating direction 222 prior to engagement, Thus, the dripless connector 210 can tolerate misalignment before being connected, and handle shock/vibe movement after being connected.

An example system 200 may support server/rack configurations that are not fully populated, allowing for half-tray applications including cooling, the use of storage trays, and other features that may be added or removed on-the-fly during operation of the system 200. For servicing and/or upgrades, operations may continue without needing to shut down other unaffected systems or stop their coolant/water flow. Individual systems may be serviced on an as-needed basis, and a single system 205 at a time may be removed via front access to the system 200. A system 205 may be compatible with a dry-disconnect cooling system, such as a 1U TBB that may move side-to-side when a computing system 205 is inserted in or removed from the rack 204.

Thus, the floating blind mate dripless connector 210 enables alternate examples to have cooling integrated into the computing system 205, for further improvements to cooling effectiveness and cost reduction. Robust blind-mate dripless connectors 210 provide a repeatable and reliable process of connection, minimizing assembly work and need for lengthy quality testing before shipping. Individual units may be serviced, and the use of an integrated valve at the dripless connector 210 avoids a need to shut down and/or remove a large portion (such as a heavy wall full of TBB units) of a rack 204. A water wall of a rack 204 may be customized for using storage trays and other features that may be individually added/removed from the example systems described herein.

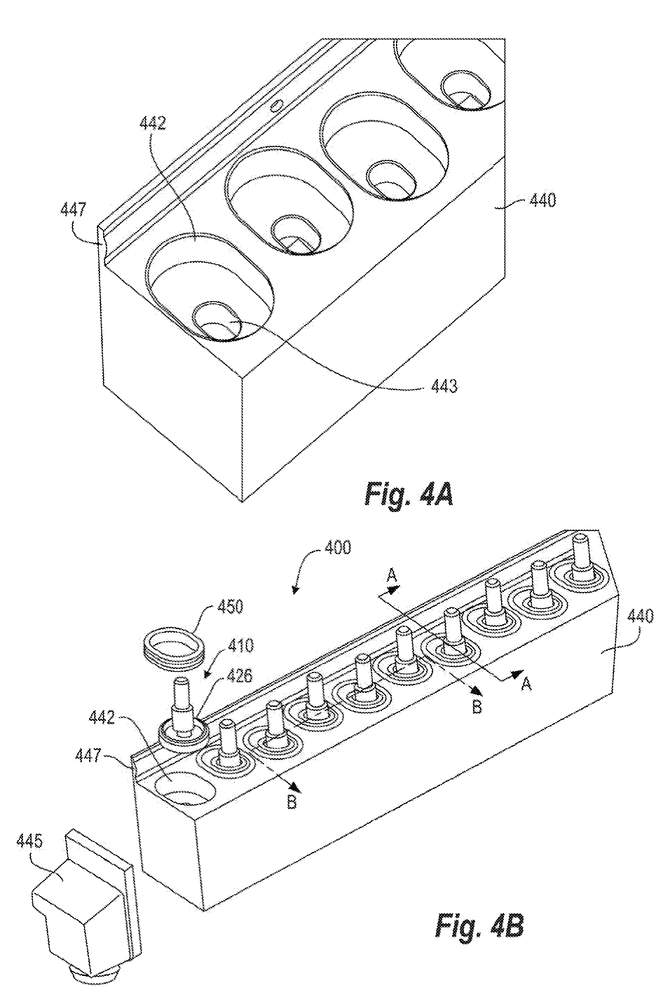

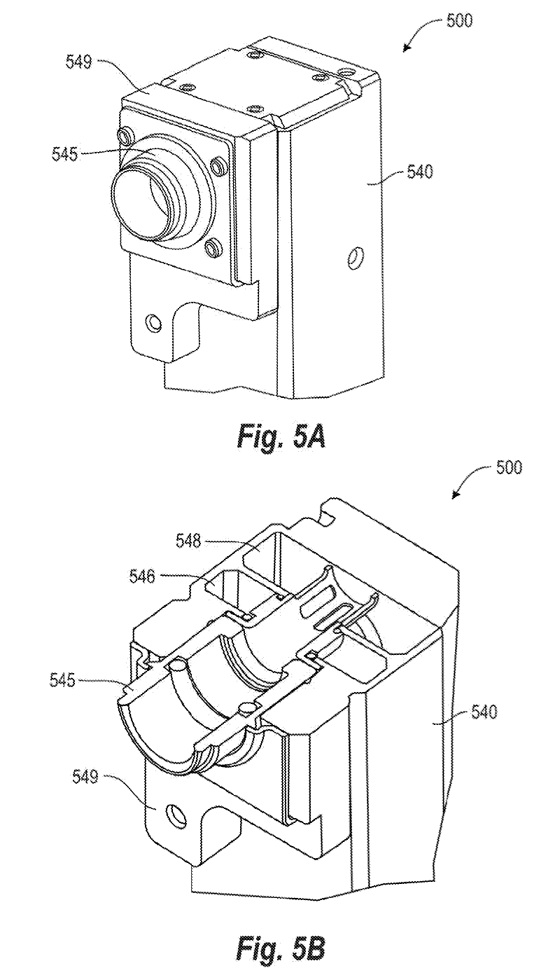

FIG. 3A is a side view of a system 300 including a dripless connector 310 according to an example. A plurality of dripless connectors 310 are slidably mounted to a manifold 340. A fitting 345 is to provide inlet and return fluid paths for the manifold 340.

In an example, the dripless connector 310 may extend 0.575-0.875 inches from the manifold 340, and the dripless connectors 310 may be spaced from each other 0.918 inches. The manifold 340 may be two inches deep, 1.475 inches wide, and 17.5 inches tall. Pairs of connectors may be arranged on 1U increments of 1.75 inches. Connectors may be offset from each other by 0.140 inches. A dripless connector may translate in the floating direction by 0.125 inches. Specific dimensions and measurements may be changed in various examples, and the foregoing are provided merely as guidelines.

FIG. 3B is a front view of a system 300 including a dripless connector 310 according to an example. A plurality of dripless connectors 310 are shown in a staggered arrangement on the manifold 340. A cap 350 is to slidably secure a dripless connector 310 to the manifold 340. The manifold 340 may support a circuit board 341. The dripless connector 310 is shown in a first position, and may be biased to the first position based on spring 360.

The blind mate dripless connector 310 may be slidably secured to the manifold 340 by a cap 350. The dripless connectors 310 are shown offset from each other in a “zig-zag” pattern. In alternate examples, the dripless connectors 310 may be aligned in a straight pattern or other pattern. The cap 350 may be secured to the manifold using various techniques, such as a press-fit arrangement. O-rings may be used in the system 300 (e.g., at the dripless connector 310, at the cap 350, at the fitting 345, etc.) to allow the dripless connector 310 to float and move while maintaining a fluid seal. The cap 350 may include a slot arranged along the floating direction, to provide clearance for the dripless connector 310 to translate freely left and right. A spring 360 may provide a biasing force to the dripless connector 310 along the floating direction. The spring 360 is to bias the dripless connector 310 to a first position, which may be aligned for coupling. The first position of the dripless connector 310 may facilitate proper connection with a corresponding mating receptacle connector, e.g., on a server cooling unit, on an in-wall TBB, or on other components/elements. The spring MO may be layered under the press-in cap 350, and in alternate examples may be placed on the same level with, or above, the cap 350 relative to the manifold 340.

The spring 360 is shown as a coil spring, and may be various other types of springs not specifically shown. In alternate examples, the spring 360 may be a full-perimeter circular spring to bias the dripless connector 310 in multiple directions, and may be a u-shaped spring for unidirectional biasing along the floating direction.

The spring 360 may be secured in the proper position by the cap 350, by the manifold 340 (e.g., in a manifold recess), and/or by the dripless connector 310. The spring 360 may thereby push against a base of the dripless connector 310, for stability and avoiding the creation of a torque moment when biasing the dripless connector 310 toward the first position. In alternate examples, the spring 360 may be omitted and the dripless connector 310 may be self-aligning within its full range of floating motion (e.g., based on use of a large lead-in and/or funnel), to safely and securely allow the dripless connector 310 to align and mate.

The system 300 may include a circuit board 341, such as a printed circuit board (PCB) or flexible circuit board etc. The circuit board 341 may include an electrical connector having spring-loaded posts or “fingers” to communicate electrical signals to/from a mated element/component. Accordingly, the circuit board 341 may communicate with various electrical features of the installed element/component, such as integrated sensors, active control valves, and so on. Accordingly, while the installed element/component may mate with a fluid connection via the dripless connector 310, it also may mate with an electrical connection via the circuit board 341. The electrical connection is to enable electrical signals such as feedback of happenings in the element/component, and/or enable the system 300 to operate/direct valves or other features of the element/component, Thus, remote control, reaction, and/or communications with coupled systems are enabled, providing information such as server temperatures, internal water temperatures, pressures, flows, and so on, while enjoying a quick connect/disconnect interface.

The circuit board 341 enables a blind-mate electrical connection to transfer signals/data without a need to separately place wiring or otherwise plug-in electrical connections when a computing system is installed (i.e., into a rack). The flexible contacts allow for sideways translation while maintaining a floating electrical connection. Spring-loaded contacts/fingers of the circuit board 341 may contact corresponding pads at the computing system, and translate side-to-side in the floating direction along with the dripless connector 310. The electrical contacts thereby may slide on the electrical contact pads without breaking the electrical connection. The circuit board 341 may be supported and aligned by the manifold 340, and the circuit board 341 may be wired to elements supporting the manifold 340 for communicating signals, such as a rack-based aggregator positioned behind the manifold (not shown). Alternate examples may support contactless technology for transmitting electrical signals and/or power, such as flow-powered sensors, radio-frequency identification (RFID), magnetics, and so on that do not need a physical direct connector link.

FIG. 4A is a perspective view of a manifold 440 according to an example. The manifold 440 includes a recess 442 to receive a dripless connector. The manifold 440 also includes a protrusion 447. The recess 442 is elongated to allow slidable movement of the dripless connector at the recess 442, while maintaining a fluid seal with the manifold 440. The recess 442 includes a passage 443 for fluid flow to/from the dripless connector.

The recess 442 is shown as a counter-bored oval recess in the manifold 440. The recess 442 may be formed using various techniques, such as machining, molding, and so on. The passage 443 enables fluid flow regardless of the position of a dripless connector. The protrusion 447 enables a mounting area, for securing the manifold 440 to other objects (such as a rack), and for securing other objects (such as a sensor) to the manifold 440. In alternate examples, the protrusion 447 may be omitted.

FIG. 4B is a partially exploded perspective view of a system 400 including a manifold 440 and a dripless connector 410 according to an example. The dripless connector 410 is received at the recess 442 of the manifold 440, and secured with the cap 450. The dripless connector 410 may include an o-ring 426. The fitting 445 may be used to couple supply/return fluid lines to the manifold 440. The line A-A corresponds to a section view shown in FIG. 6A, and the line B-B corresponds to a section view shown in FIG. 6B.

The exploded view shows cap 450 being assembled to manifold 400 based on a press-fit, such as an interference fit. In alternate examples, the cap 450 may be removably secured to the manifold 440 by fasteners or other techniques.

The dripless connector 410 may be sealed to the cap 450 and/or the manifold 440 based on o-rings 426. An o-ring 426 may be used on a top surface of the dripless connector 410 to seal against the cap 450, and an o-ring 426 may be used on a bottom of the dripless connector 410 to seal against the manifold 440.

The fitting 445 may send/receive fluid flow to/from the manifold 440. The fitting 445 may be fit to an end of the manifold 440. The manifold 440 may include end passages (not shown) to allow flow to/from the fitting 445. In alternate examples, the fitting 445 may be omitted, and supply/return fluid lines may be coupled to the manifold 440 without the separate fitting 445 (e.g., based on connectors boring directly into the manifold 440).

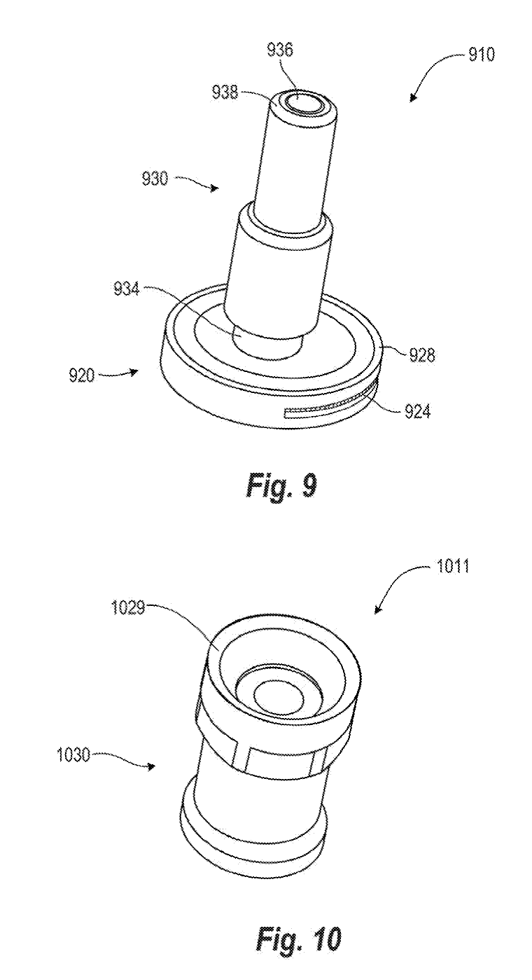

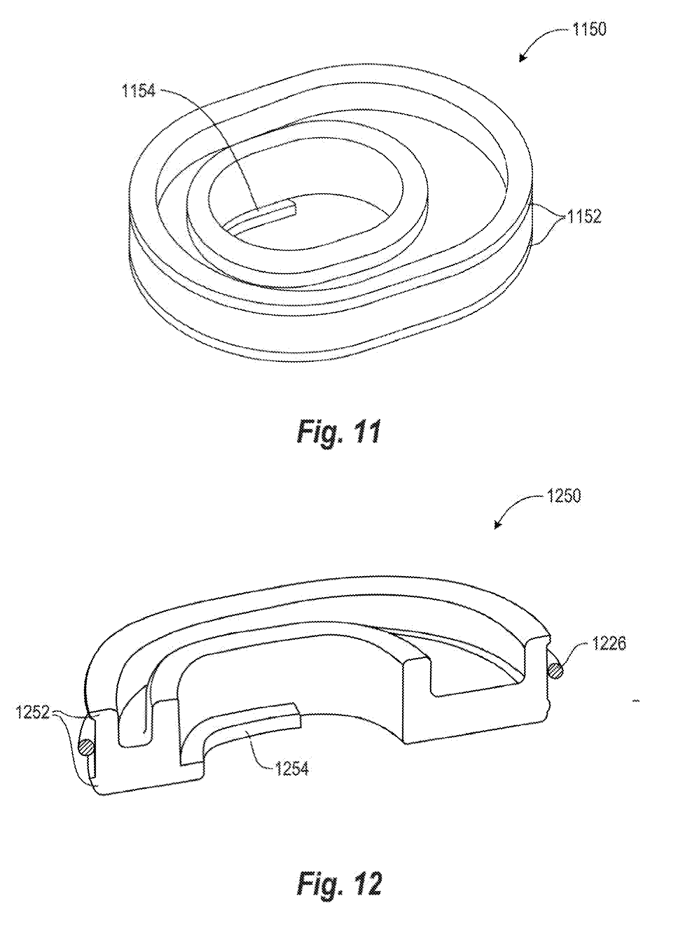

FIG. 5A is a perspective view of a system 500 including a manifold 540 according to an example. The manifold 540 includes a fitting 545 and a plate 549. The fitting 545 may be coupled directly to the manifold 540, without a need for the end-cap style of fitting as shown in FIG. 4B, The plate 549 may be used to secure the fitting 545 via removable fasteners. In an alternate example, the plate 549 also may be used as a removable cap to secure a floating dripless connector (not shown in FIG. 5A), and/or may be used to removably secure a cap itself (not shown in FIG. 5A).

FIG. 5B is a perspective section view of a system 500 including a manifold 540 according to an example. The manifold 540 includes a fitting 545 and a plate 549. The manifold 540 includes a first chamber 546 and a second chamber 548.

The manifold 540 is shown divided front from back to provide the first chamber 546 and the second chamber 548. The fitting 545 is shown bypassing fluid communication with the first chamber 546, and enabling fluid communication with the second chamber 548. Similarly, a dripless connector (not shown) may selectively enable fluid communication with the first chamber 546 and second chamber 548 based on a depth of the connector, enabling such dripless connectors to be in-line with each other without a zig-zag offset shown in other drawings, while still alternating between supply and return chambers of the manifold 540.

FIG. 6A is a section view, taken along line A-A of FIG. 4B, of a system 600 including a dripless connector 610 according to an example. A base 620 of the dripless connector 610 is secured to a manifold 640 by a cap 650. The base 620 and/or cap 650 may include o-rings 626. An extension 630 of the dripless connector 610 may extend away from the manifold 640 through the cap 650. The manifold 640 includes a protrusion 647 and passage 643.

A spring (not shown) may be positioned between the manifold 640 and the base 620 of the dripless connector 610 (to the right of the base 620 as illustrated), to bias the dripless connector 610 toward the first position (to the left as illustrated). O-rings 626 enable a fluid seal between the base 620 and the cap 650 and manifold 640. Translation of the connector 610 enables fluid flow to be maintained via the passage 643.

FIG. 6B is a section view, taken along line B-B of FIG. 4B, of a system 600 including a dripless connector 610 according to an example. A plurality of dripless connectors 610 are shown in communication with first chamber 646 and second chamber 648 via passages 643.

The section view cuts through a center of two dripless connectors, and through a portion of two of the dripless connectors 610, illustrating the zig-zag offset between dripless connectors 610. The offset enables two of the illustrated dripless connectors 610 to be in fluid communication with the first chamber 646, and two of the illustrated dripless connectors 610 to be in fluid communication with the second chamber 648 (where the first and second chambers 646, 648 are defined by a zig-zag divider, e.g., as shown in FIG. 7).

FIG. 7 is a perspective view of a system 700 including a manifold 740 according to an example. The manifold 740 is shown from a back side with a back plate removed for visibility, revealing a divider 744 separating the manifold 740 into first chamber 746 and second chamber 748. The manifold 740 is in fluid communication via passages 743 alternating between the first chamber 746 and second chamber 748. The first chamber 746 and/or second chamber 748 are also in fluid communication with the fitting 745 (passages in the manifold 740 to the fitting 745 are not shown in FIG. 7).

The divider 744 is zig-zag to accommodate a geometry of arrangement of the dripless connectors that would extend from the opposite side of the manifold (not shown), partitioning between hot and cold (supply and return) fluid paths of the first chamber 746 and second chamber 748. The divider may be insulated, based on plastic (e.g., a metal manifold 740 having a plastic divider 744 separating the fluid paths). The insulated divider 744 is to minimize thermal conduction between the first chamber 746 and the second chamber 748, The manifold 740 and/or divider 744 (as well as any other component of the example systems throughout) may be constructed using techniques such as die cast, extrusion, injection molding, machining, epoxy, welding, and so on, including combinations of techniques. The manifold 740 may be sealed with a back plate (not shown) to create an enclosed volume with the first chamber 746 and second chamber 748.

FIG. 8 is a perspective view of a system 800 including a manifold 840 and dripless connector 810 according to an example. Dripless connector 810 may be slidable at recess 842 of the manifold 840. The dripless connector 810 may include an o-ring 826. The cap (not shown) to secure the dripless connector 810 to the manifold 840 is removed, to illustrate a first position 812 and a second position 814 of the dripless connector 810 superimposed over each other. An extent of the floating/slidable movement of the dripless connector 810 is visible, enabled by the elongated recess 842 and corresponding shape of a base of the dripless connector 810.

The dripless connector 810 is shown with a floating range of motion of 0.125 inches between the first position 812 and the second position 814, although larger or smaller ranges are possible in alternate examples (e.g., by using a wider elongated recess 842 or narrower base for the dripless connector 810). A biasing spring (not shown) may be positioned in the gap between the recess 842 and base of the connector 810, i.e., to the left of the base of the dripless connector 810. A cap (not shown). when inserted, may secure the spring and dripless connector 810 in place at the manifold 840.

FIG. 9 is a perspective view of a dripless connector 910 according to an example. The dripless connector 910 includes a base 920 and an extension 930. The base 920 includes a cutout 924 and a lip 928. The extension 930 includes an undercut 934, a valve 936, and a bevel 938.

The base 920 of the dripless connector 910 may be elongated, to mate with a recess of the manifold. The base 920 is shown generally as an oval, and other shapes are possible including a circle, square, rectangle, and so on. A corresponding accommodating shape at the manifold may be used (e.g., a corresponding manifold recess, or plate on the surface of the manifold in examples where a recess is not used for slidably mounting the dripless connector).

The base 920 may include a lip 928, shown as an upper raised perimeter lip structure corresponding to an upper o-ring (not shown). A lower lip (not shown) also may be used, corresponding to a lower o-ring (not shown) at an underside of the base 920. The lip 928 may be formed as a wall to minimize over-deflection/tilting of the dripless connector 910, to retain the o-ring's shape and prevent over-compression and leakage of the o-ring.

The base 920 may include cutout 924. Cutout 924 may be a circular portion, shaped to accommodate a biasing spring (not shown). Thus, cutout 924 may be a hole corresponding to a traditional coil spring, an arc (as shown) corresponding to a U-shaped spring around a portion of the perimeter (e.g., to bias the base 920 toward a first position), and other shapes.

The extension 930 of the dripless connector 910 includes a lead-in bevel 938, and an undercut 934. The bevel 938 is to facilitate blind-mating and self-alignment of the dripless connector 910. The undercut 934 is to allow space for a ledge of a cap (not shown) to surround the extension, to provide a fluid seal and secure/stabilize the dripless connector 910 to ensure smooth translation along the floating direction and minimize deflection/tilting of the extension 930 during self-alignment.

FIG. 10 is a perspective view of a female dripless connector 1011 according to an example. Female dripless connector 1011 includes an extension 1030 coupleable to an extension from a male dripless connector, such as the extension 930 of dripless connector 910 of FIG. 9. Female dripless connector 1011 may include a funnel 1029, shown in FIG. 10 as generally circular (although elongated and other shapes are possible).

The female dripless connector 1011 provides a smaller body size for coupling with the dripless connector 910, while including a larger funnel 1029 for blind-mating self-alignment. The funnel 1029 may be wide enough to accommodate a range of motion of the dripless connector 910. Thus, the funnel 1029 may provide a “don't-care” alignment feature, allowing omission of a biasing spring for the dripless connector 910, and enabling self-alignment even if a connector is not in a first position. The funnel can self-align the dripless connector 910 to bring it to the first position during engagement, regardless of whether the corresponding connector is biased.

FIG. 11 is a perspective view of a cap 1150 according to an example. The cap 1150 includes an overlap 1152 and ledge 1154. The overlap 1152 is to contact the manifold (not shown), to provide a secure fit and seal. The ledge 1154 is at a base of the cap 1150 to provide a sealing surface for an o-ring (not shown) of a base of the dripless connector (not shown) to contact, regardless of translation and/or floating movement of the dripless connector. The ledge 1154 also may help to retain and align an undercut of the dripless connector. The ledge 1154 is positioned along an inner perimeter of the cap 1150. A portion of the ledge 1154 is removed (toward the right as shown in FIG. 11), to enable a large range of translation of the dripless connector toward the removed area.

FIG. 12 is a perspective section view of a cap 1250 according to an example. The cap 1250 includes o-ring 1226, overlap 1252, and ledge 1254. The cap 1250 may be formed of a rigid material such as metal. Thus, the overlap 1252 may form a rigid barbed interface for a press-fit seal against the manifold (not shown). The manifold also may be metal to engage with the overlap 1252 in an interference pressed fit. The angled/barbed feature of the overlap 1252 enables the cap to be smoothly insertable into a recess of the manifold, such that the barb of the overlap 1252 may bite in to the manifold and prevent the cap 1250 from being ejected from the manifold when experiencing fluid pressure. The o-ring 1226 may be placed around an outside of the cap, ensuring a fluid seal at the junction between the cap 1250 and manifold to withstand fluid pressure. The cap 1250 may be made of various materials to withstand fluid pressure and maintain integrity with the manifold. In an example, the cap 1250 may be formed of a material as hard as, or harder than, the manifold, enabling the barbed overlap 1252 to bite into and grip the manifold. In an alternate example, the barbed overlap 1252 may be formed on the manifold to bite into the cap 1250. In yet another alternate example, the overlap may be omitted and the cap 1250 may be removably secured with fasteners and/or a plate (e.g., similar to the plate 549 of FIG. 5A), to enable inspection, repairing, changing, and other servicing of the dripless connector, manifold, passageways, and other features of the dripless connector systems accessible by removing the cap 1250 from the manifold.

FIG. 13 is a perspective view of a system 1300 including a dripless connector 1310 according to an example. Manifold 1340 includes a plurality of male dripless connectors 1310 coupled to corresponding female dripless connectors 1311 associated with an element 1302 (e.g., a thermal bus bar of a computing system). The manifold 1340 also includes a fitting 1345 and protrusion 1347.

As shown, two of the dripless connectors 1310 are engaged with the element 1302. Accordingly, the element 1302 may float with respect to the manifold 1340, without causing damage or leakage due to the floating dripless connectors 1310 maintaining a fluid seal. Furthermore, the element 1302 may fully receive the benefits from fluid flow to/from the manifold 1340, even though the upper dripless connector 1310 is disconnected. The element 1302 may engage the dripless connectors 1310 by moving toward the right as illustrated in FIG. 13, along an engagement direction. The dripless connectors 1310 are slidable along a floating direction, shown as upward and leftward in FIG. 13. Accordingly, the engagement direction of the dripless connectors 1310 is substantially non-parallel to the floating direction. In alternate examples, the interface between the engaged connectors may allow some movement/tolerance without breaking the fluid seal.

What is claimed is:

1. A system comprising:
a dripless connector including a base and an extension;
a manifold to slidably mount the dripless connector in fluid communication with the manifold, wherein the base of the dripless connector is slidable, relative to the manifold, along a floating direction substantially non-parallel to an engagement direction of the extension of the dripless connector.

2. The system of claim 1, further comprising a cap to slidably secure the base of the dripless connector to the manifold.

3. The system of claim 2, wherein an outer perimeter of the cap includes an overlap to engage the manifold, and an inner perimeter of the cap includes a ledge to engage an undercut of the extension of the dripless connector.

4. The system of claim 1, further comprising a spring to bias the dripless connector toward a first position along the floating direction.

5. The system of claim 4, wherein the base of the dripless connector includes a cutout to provide clearance for the spring, and the spring is to bias against the base of the dripless connector.

6. The system of claim 1, further comprising a plurality of dripless connectors that are independently slidable at the manifold.

7. The system of claim 1, wherein the extension of the dripless connector includes an automatic integrated shut-off valve and a beveled lead-in associated with blind-mating.

8. The system of claim 1, wherein the base of the dripless connector includes an o-ring to fluidly seal the dripless connector to the manifold.

9. The system of claim 8, wherein the base of the dripless connector includes a lip to prevent over-compression of the o-ring.

10. The system of claim 1, wherein the manifold includes a recess to slidably mount the base of the dripless connector.

11. The system of claim 10, wherein the manifold includes an insulated divider to divide the manifold into a first chamber for inlet fluid flow and a second chamber for return fluid flow.

12. A system comprising:
a dripless connector;
a manifold including a recess to slidably mount the dripless connector in fluid communication with the manifold, wherein the dripless connector is slidable between a first position and a second position while maintaining a fluid seal;
a spring to bias the dripless connector toward the first position along the floating direction; and
a cap to slidably secure the dripless connector to the manifold.

13. The system of claim 12, wherein the dripless connector includes a base and an extension, wherein the extension of the dripless connector is quick-connect and includes a beveled lead-in and an automatic shut-off valve, and the base of the dripless connector is to seal against the cap and the oblong recess of the manifold.

14. A system, comprising:
a dripless connector; and
a manifold including a recess to slidably mount the dripless connector in fluid communication with the manifold;
wherein the dripless connector is to connect to an element of a computing system along a first direction of engagement, and wherein the dripless connector is slidable along a floating direction to allow the element of the computing system to be movable.

15. The system of claim 14, wherein the dripless connector is unbiased along a range of motion along its slidable mount to the manifold, and an extension of the dripless connector is to self-align within the range of motion to an appropriate engagement position based on connecting with the element of the computing system.
